(19) United States
(12) Patent Application Publication
(10) Pub. No.: US 2023/0386871 A1
(43) Pub. Date: Nov. 30, 2023

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Naoki HARA, Toyama (JP); Shin HIYAMA, Toyama (JP); Taiyo OKAZAKI, Toyama (JP)

(21) Appl. No.: 18/446,948

(22) Filed: Aug. 9, 2023

Related U.S. Application Data
(63) Continuation of application No. PCT/JP2022/001193, filed on Jan. 14, 2022.

(30) Foreign Application Priority Data
Mar. 15, 2021 (JP) 2021-041543

(51) Int. Cl. H01L 21/67; H01L 21/687

(52) U.S. Cl. CPC H01L 21/67201; H01L 21/67248; H01L 21/68764; H01L 21/67017

(57) ABSTRACT

According to one embodiment of the present disclosure, there is provided a technique that includes: a load lock chamber into which a substrate is loaded and from which the substrate is unloaded; a substrate support provided in the load lock chamber and configured to support a plurality of substrates comprising the substrate in a multistage manner with a predetermined interval therebetween; and a temperature sensor capable of measuring a temperature of the substrate support in a non-contact manner while the plurality of substrates are supported by the substrate support.

### CROSS REFERENCE TO RELATED APPLICATIONS

This application is a bypass continuation application of PCT International Application No. PCT/JP2022/001193, filed on Jan. 14, 2022, in the WIPO, the international application being based upon and claiming the benefit of priority from Japanese Patent Application No. 2021-041543, filed on Mar. 15, 2021, in the Japanese Patent Office, the entire contents of which are hereby incorporated by reference.

### TECHNICAL FIELD

The present disclosure relates to a substrate processing apparatus, a method of manufacturing a semiconductor device and a non-transitory computer-readable recording medium.

### BACKGROUND

Conventionally, a substrate processing apparatus provided with a load lock chamber may be used. A substrate may be transferred (loaded) into the load lock chamber or transferred (unloaded) from the load lock chamber. According to some related arts, the load lock chamber of the substrate processing apparatus is provided with a function of switching an inner atmosphere of the load lock chamber between an atmospheric state and a vacuum state.

However, in the substrate processing apparatus, the substrate loaded into the load lock chamber may be unloaded from the load lock chamber to an atmospheric pressure region without being cooled to a desired temperature.

### SUMMARY

According to the present disclosure, there is provided a technique capable of obtaining a temperature of a substrate in a load lock chamber.

According to one embodiment of the present disclosure, there is provided a technique that includes: a load lock chamber into which a substrate is loaded and from which the substrate is unloaded; a substrate support provided in the load lock chamber and configured to support a plurality of substrates comprising the substrate in a multistage manner with a predetermined interval therebetween; and a temperature sensor capable of measuring a temperature of the substrate support in a non-contact manner while the plurality of substrates are supported by the substrate support.

### BRIEF DESCRIPTION OF THE DRAWINGS

FIG. 1 is a diagram schematically illustrating a configuration of a substrate processing apparatus according to one or more embodiments of the present disclosure.

FIG. 2 is a diagram schematically illustrating a vertical cross-section of the substrate processing apparatus according to the embodiments of the present disclosure.

FIG. 3 is a diagram schematically illustrating a vertical cross-section of a load lock chamber the substrate processing apparatus according to the embodiments of the present disclosure.

FIG. 4 is a diagram schematically illustrating a state in which a temperature sensor measures a temperature of a boat in the substrate processing apparatus according to the embodiments of the present disclosure.

FIG. 5 is a flow chart schematically illustrating a flow of determining whether or not a substrate is capable of being unloaded from the load lock chamber to an atmospheric transfer chamber in the substrate processing apparatus according to the embodiments of the present disclosure.

FIG. 6 is a block diagram schematically illustrating a configuration of a controller and related components of the substrate processing apparatus according to the embodiments of the present disclosure.

### DETAILED DESCRIPTION

### Embodiments of Present Disclosure

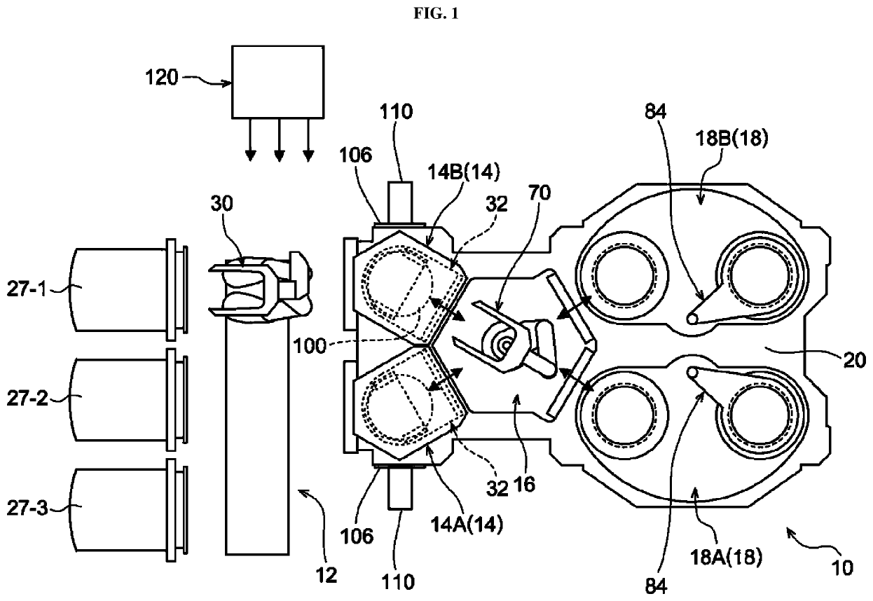

Hereinafter, one or more embodiments (also simply referred to as “embodiments”) according to the technique of the present disclosure will be described with reference to FIGS. 1 through 6. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

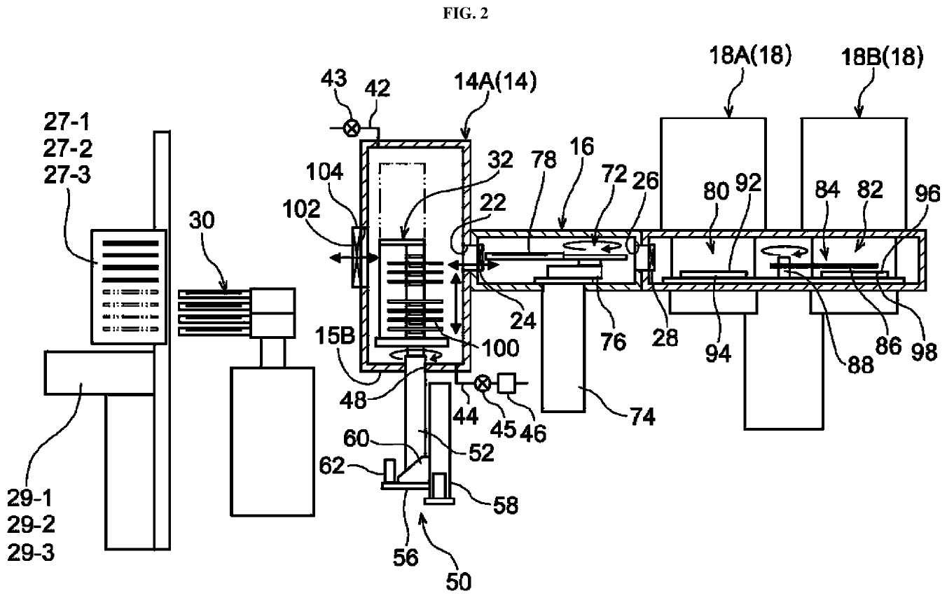

As shown in FIGS. 1 and 2, a substrate processing apparatus 10 according to the present embodiments may include: an atmospheric transfer chamber (EFEM: Equipment Front End Module) 12; loading port structures 29-1, 29-2 and 29-3 connected to the atmospheric transfer chamber 12 and serving as mounting structures on which pods 27-1, 27-2 and 27-3 serving as substrate storage containers are placed; load lock chambers 14A and 14B serving as pressure-controlled preliminary chambers; a transfer chamber 16 serving as a vacuum transfer chamber; and process chambers 18A and 18B in which a plurality of substrates including a substrate 100 are processed. Hereinafter, the plurality of substrates including the substrate 100 may also be referred to as “substrates 100”. Further, a partition wall (which is a boundary wall) 20 is provided so as to separate the process chamber 18A and the process chamber 18B. According to the present embodiments, a semiconductor wafer such as a silicon wafer on which a semiconductor device is manufactured may be used as the substrate 100.

According to the present embodiments, configurations of the load lock chambers 14A and 14B (including configurations associated with the load lock chambers 14A and 14B) are substantially the same. Therefore, the load lock chambers 14A and 14B may also be collectively or individually referred to as a “load lock chamber 14”.

Further, according to the present embodiments, configurations of the process chambers 18A and 18B (including configurations associated with the process chambers 18A and 18B) are substantially the same. Therefore, the process chambers 18A and 18B may also be collectively or individually referred to as a “process chamber 18”.

As shown in FIG. 2, a communication structure 22 is provided between the load lock chamber 14 and the transfer chamber 16 so as to communicate between adjacent chambers (that is, the load lock chamber 14 and the transfer chamber 16). The communication structure 22 is configured to be opened or closed by a gate valve 24.

As shown in FIG. 2, a communication structure 26 is provided between the transfer chamber 16 and the process chamber 18 so as to communicate between adjacent chambers (that is, the transfer chamber 16 and the process chamber 18). The communication structure 26 is configured to be opened or closed by a gate valve 28.

An atmospheric robot 30 serving as an atmospheric transfer structure is provided in the atmospheric transfer chamber 12. The atmospheric robot 30 is capable of transferring the substrate 100 between the load lock chamber 14 and each of the pods 27-1 through 27-3 placed on the loading port structures 29-1 through 29-3, respectively. The atmospheric robot 30 is configured to be capable of simultaneously transferring two or more substrates among the substrates 100 in the atmospheric transfer chamber 12.

The load lock chamber 14 is configured such that the substrate 100 is transferred (loaded) into or transferred (unloaded) out of the load lock chamber 14. Specifically, an unprocessed substrate among the substrates 100 is loaded into the load lock chamber 14 by the atmospheric robot 30. Hereinafter, the unprocessed substrate among the substrates 100 may also be simply referred to as an “unprocessed substrate 100”. The unprocessed substrate 100 loaded into the load lock chamber 14 is then unloaded out of the load lock chamber 14 by a vacuum robot 70 described later. On the other hand, a processed substrate among the substrates 100 is loaded into the load lock chamber 14 by the vacuum robot 70. Hereinafter, the processed substrate among the substrates 100 may also be simply referred to as a “processed substrate 100”, and processed substrates among the substrates 100 may also be simply referred to as “processed substrates 100”. The processed substrate 100 loaded into the load lock chamber 14 is then unloaded out of the load lock chamber 14 by the atmospheric robot 30.

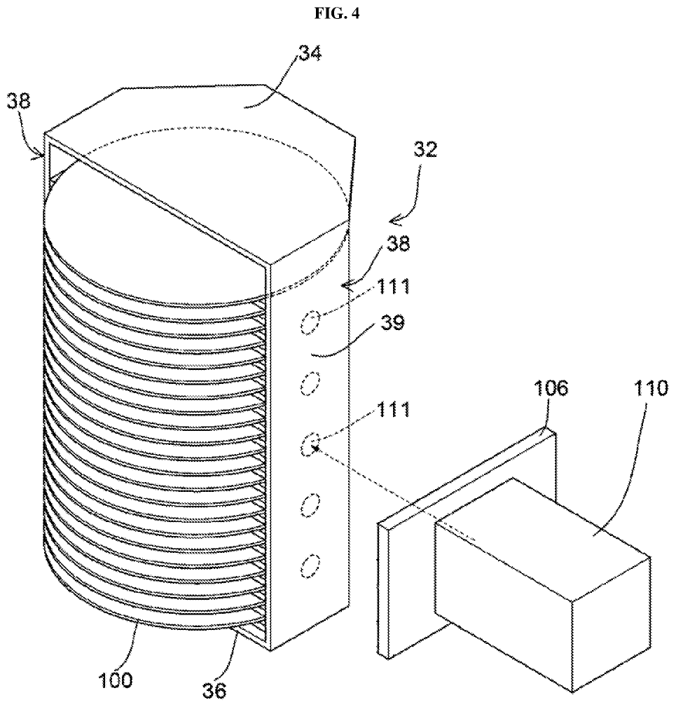

Further, a boat 32 serving as a substrate support capable of supporting the substrate 100 is provided in the load lock chamber 14. As shown in FIG. 4, the boat 32 is provided so as to support the substrates (for example, 10 substrates to 30 substrates) 100 in a multistage manner with a predetermined interval therebetween and so as to accommodate the substrates 100 in a horizontal orientation. Specifically, the boat 32 may be embodied by a structure in which an upper plate 34 and a lower plate 36 are connected by a plurality of support columns (for example, three support columns) 38.

For example, a plurality of support recesses (for example, 10 to 30 support recesses) including a support recess 40 configured to support the substrate 100 are provided at inner sides of the support columns 38 along a longitudinal direction. Hereinafter, the plurality of support recesses including the support recess 40 may also be simply referred to as “support recesses 40”. The support recesses 40 are provided parallel to one another at a predetermined interval therebetween.

For example, a vertical surface 39 is provided on an outer surface (which is a surface opposite to the support recess 40) of one of the support columns 38. The vertical surface 39 extends in a direction perpendicular to a plate surface of the substrate 100 (the same direction as a vertical direction in the present embodiments) while the substrate 100 is supported by the boat 32. In addition, a thickness of the one of the support columns 38 is set to be constant at a portion where the vertical surface 39 is provided.

For example, the boat 32 may be made of a metal material, preferably a metal material whose thermal conductivity is high (for example, iron, copper and aluminum).

For example, in a case where the boat 32 is made of aluminum, from a viewpoint of a temperature measurement using a temperature sensor 110 described later, it is preferable to perform an alumite treatment on the vertical surface 39.

A gas supply pipe 42 communicating with an inside of the load lock chamber 14 is connected to a top plate 15A constituting the load lock chamber 14. A gas supply source (not shown) capable of supplying an inert gas (for example, nitrogen gas or a rare gas) and a gas supply valve 43 are sequentially provided at the gas supply pipe 42 in this order from an upstream side toward a downstream side of the gas supply pipe 42 along a gas flow direction. The gas supply pipe 42 and the gas supply valve 43 may also be collectively referred to as an “inert gas supplier” (which is an inert gas supply structure or an inert gas supply system). The inert gas supplier may also be simply referred to as a “supplier”. The inert gas supplier may further include the gas supply source.

For example, a cooling structure (not shown) such as a coolant circulation channel is provided at the top plate 15A. The substrate 100 supported by the boat 32 can be cooled by the cooling structure. Specifically, the processed substrate 100 heated after being processed in the process chamber 18 is cooled by the cooling structure.

An exhaust pipe 44 communicating with the inside of the load lock chamber 14 is connected to a bottom plate 15B constituting the load lock chamber 14. A valve 45 and a vacuum pump 46 serving as a vacuum exhaust apparatus are sequentially provided at the exhaust pipe 44 in this order from an upstream side toward a downstream side of the exhaust pipe 44 along the gas flow direction.

According to the present embodiments, the gas supply valve 43 is closed while the communication structures 22 and 26 are closed by the gate valves 24 and 28, respectively. In such a state, when the valve 45 is opened and the vacuum pump 46 is operated, an inner atmosphere of the load lock chamber 14 is vacuum exhausted such that an inner pressure of the load lock chamber 14 can be set (adjusted) to a vacuum pressure (or a decompressed state). In addition, in a state in which the communication structures 22 and 26 are closed by the gate valves 24 and 28, respectively, when the valve 45 is closed (or an opening degree of the valve 45 is reduced) and the gas supply valve 43 is opened to supply the inert gas into the load lock chamber 14, the inner pressure of the load lock chamber 14 can be set to an atmospheric pressure.

As shown in FIG. 2, an opening 102 is provided on an outer peripheral wall 15C constituting the load lock chamber 14. The substrate 100 can be loaded into or unloaded from the load lock chamber 14 through the opening 102. Specifically, the opening 102 is provided on the outer peripheral wall 15C so as to face the atmospheric robot 30. The atmospheric robot 30 is configured to transfer the substrate 100 to the boat 32 through the opening 102 such that the substrate 100 is supported by the boat 32 and to transfer (take out) the substrate 100 from the boat 32 through the opening 102.

For example, a gate valve 104 capable of opening and closing the opening 102 is provided on the outer peripheral wall 15C.

For example, a window 106 is provided on the outer peripheral wall 15C. For example, the window 106 is made of a material capable of transmitting an infrared light. For example, germanium may be used as the material constituting the window 106.

A temperature sensor 110 is provided on an outer side of the window 106. In other words, the temperature sensor 110 is arranged at an outer side of the load lock chamber 14. The temperature sensor 110 is a sensor capable of measuring a temperature of the boat 32 in the load lock chamber 14 in a non-contact manner. That is, the temperature sensor 110 is a non-contact type temperature sensor. Specifically, the temperature sensor 110 measures the temperature of the boat 32 in the non-contact manner while the processed substrate 100 is supported by the boat 32. For example, the temperature sensor 110 is a radiation thermometer, and measures the temperature of the boat 32 by measuring an intensity of the infrared light emitted (or radiated) from the boat 32. More specifically, the temperature sensor 110 measures the temperature of the boat 32 by measuring the intensity of the infrared light emitted from the vertical surface 39 of the boat 32. Further, when the temperature of the boat 32 is measured, a driving structure 50 is controlled by a controller 120 described later such that a temperature measurement range 111 of the temperature sensor 110 lies within the vertical surface 39 of the boat 32. Specifically, the controller 120 controls the driving structure 50 to adjust an elevation position and a rotation angle of the boat 32 such that the temperature measurement range 111 of the temperature sensor 110 lies within the vertical surface 39 of the boat 32. FIG. 4 including the temperature measurement range 111 is a diagram schematically illustrating an example in which five temperature measurement ranges including the temperature measurement range 111 are set at approximately the same interval in an up-and-down direction of the vertical surface 39 and the temperature is measured in each of the five temperature measurement ranges including the temperature measurement range 111. According to the present embodiments, for example, a radiation thermometer (which is a non-contact type temperature sensor) is used as the temperature sensor 110. However, a pyrometer may be used as the temperature sensor 110.

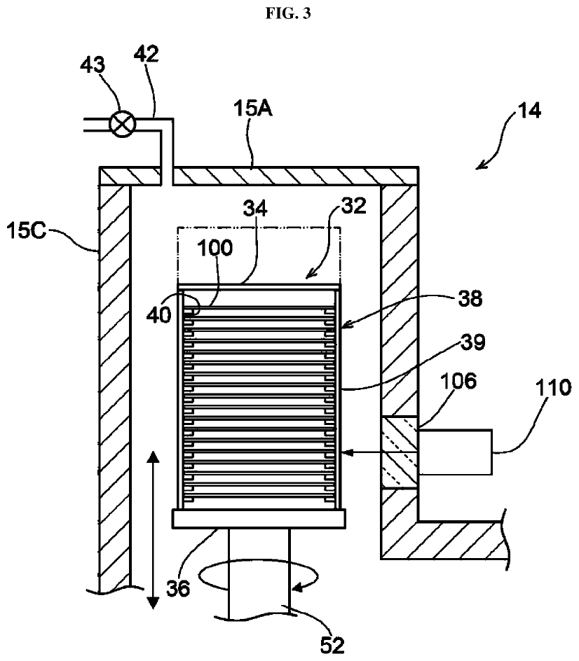

Further, the temperature sensor 110 is provided at a position at which the temperature of the boat 32 can be measured. More specifically, by elevating or lowering the boat 32, the temperature sensor 110 can measure a temperature of an upper end of the boat 32 and a temperature of a lower end of the boat 32 as the temperature of the boat 32. For example, according to the present embodiments, as shown in FIG. 3, the temperature sensor 110 is arranged on a lower portion of the outer peripheral wall 15C. Thereby, when the boat 32 is elevated to the highest position, the temperature of the lower end of the boat 32 can be measured as the temperature of the boat 32 by the temperature sensor 110.

An opening 48 communicating the inside and outside of the load lock chamber 14 is provided at the bottom plate 15B of the load lock chamber 14. The driving structure 50 capable of elevating and lowering the boat 32 and rotating the boat 32 through the opening 48 is provided below the load lock chamber 14.

The driving structure 50 may include: a shaft 52 serving as a support shaft capable of supporting the boat 32; a bellows (which is extendable and retractable, not shown) provided so as to surround the shaft 52; a fixing base 56 to which lower ends of the shaft 52 and the bellows are fixed; an elevation driver (which is an elevation driving structure) 58 capable of elevating and lowering the boat 32 via the shaft 52; a connection structure 60 capable of connecting the elevation driver 58 and the fixing base 56; and a rotation driver (which is a rotation driving structure) 62 capable of rotating the boat 32.

The elevation driver 58 is configured to elevate or lower the boat 32 along a direction in which the substrates 100 are stacked in the multistage manner.

An upper end of the bellows is fixed around the opening 48 provided in the bottom plate 15B constituting the load lock chamber 14.

The rotation driver 62 is configured to rotate the boat 32 about an axis extending along the direction in which the substrates 100 are stacked in the multistage manner. That is, the rotation driver 62 is configured perform a rotation operation for the boat 32. Specifically, the rotation driver 62 rotates the boat 32 around the shaft 52 serving as a rotation axis.

The vacuum robot 70 serving as a vacuum transfer structure is provided in the transfer chamber 16. The vacuum robot 70 is configured to transfer the substrate 100 between the load lock chamber 14 and the process chamber 18. The vacuum robot 70 may include: a substrate transfer structure 72 capable of supporting and transferring the substrate 100; and a transfer driver (which is a transfer driving structure) 74 capable of rotating the substrate transfer structure 72 and elevating or lowering the substrate transfer structure 72.

An arm structure 76 is provided in the substrate transfer structure 72. The arm structure 76 is provided with a finger 78 on which the substrate 100 is placed. Alternatively, a plurality of fingers including the finger 78 may be provided on the arm structure 76 at a predetermined interval therebetween in the vertical direction. For example, a plurality of arm structures including the arm structure 76 may be provided in a multistage manner. In addition, the finger 78 is configured to be extendable and retractable in a substantially horizontal direction.

The substrate 100 can be moved from the load lock chamber 14 to the process chamber 18 by moving the substrate 100 supported by the boat 32 into the transfer chamber 16 by the vacuum robot 70 via the communication structure 22 and further moving the substrate 100 into the process chamber 18 by the vacuum robot 70 via the communication structure 26.

Further, the substrate 100 can be moved from the process chamber 18 to the load lock chamber 14 by moving the substrate 100 in the process chamber 18 into the transfer chamber 16 by the vacuum robot 70 via the communication structure 26 and then by supporting the substrate 100 on the boat 32 by the vacuum robot 70 via the communication structure 22.

A first process structure 80, a second process structure 82 located farther from the transfer chamber 16 than the first process structure 80 and a substrate mover (which is a substrate moving structure) 84 capable of transferring the substrate 100 between the second process structure 82 and the vacuum robot 70 are provided in the process chamber 18.

The first process structure 80 may include a first mounting table 92 on which the substrate 100 is placed and a first heater 94 configured to heat the first mounting table 92.

The second process structure 82 may include a second mounting table 96 on which the substrate 100 is placed and a second heater 98 configured to heat the second mounting table 96.

The first process structure 80 and the second process structure 82 are configured to process the substrate 100 likewise (that is, in the same manner).

The substrate mover 84 is constituted by a mover (which is a moving structure) 86 capable of supporting the substrate 100 and a moving shaft 88 provided in the vicinity of the partition wall 20. The mover 86 is provided so as to be rotatable around the moving shaft 88 serving as a rotation axis. Further, the mover 86 can be elevated and lowered around the moving shaft 88.

For example, by rotating the mover 86 toward the first process structure 80, the substrate mover 84 is capable of transferring the substrate 100 to or from the vacuum robot 70 at the first process structure 80. Thereby, the substrate mover 84 is capable of moving the substrate 100 transferred by the vacuum robot 70 to the second mounting table 96 of the second process structure 82 and also capable of moving the substrate 100 placed on the second mounting table 96 to the vacuum robot 70.

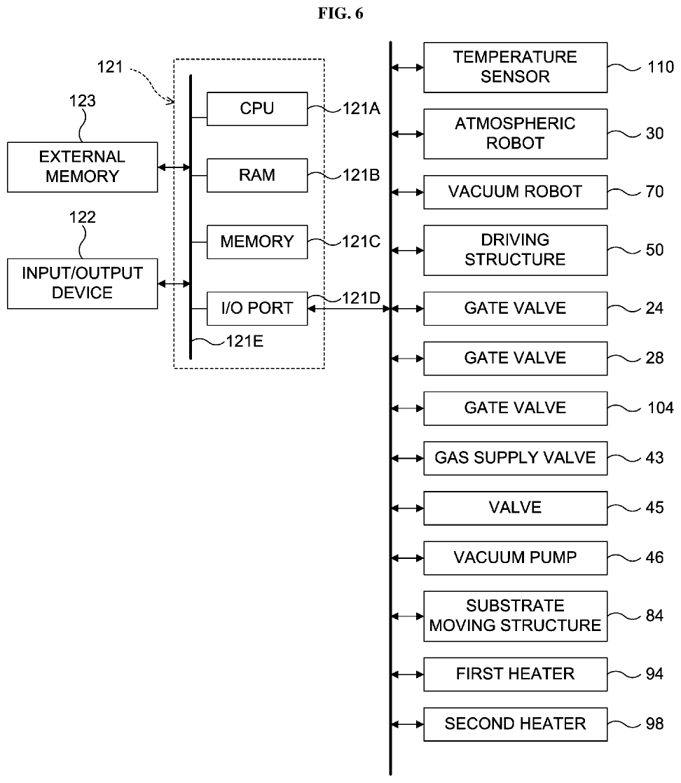

As shown in FIG. 6, the substrate processing apparatus 10 includes the controller 120 serving as a control structure. For example, the controller 120 is constituted by a computer including a CPU (Central Processing Unit) 121A, a RAM (Random Access Memory) 121B, a memory 121C and an I/O port (input/output port) 121D.

The RAM 121B, the memory 121C and the I/O port 121D may exchange data with the CPU 121A through an internal bus 121E. For example, an input/output device 122 constituted by components such as a touch panel may be connected to the controller 120.

For example, the memory 121C is configured by a component such as a flash memory and a hard disk drive (HDD). For example, a control program configured to control operations of the substrate processing apparatus 10 and a process recipe containing information on sequences and conditions of a substrate processing described later may be readably stored in the memory 121C. The process recipe is obtained by combining steps of the substrate processing described later such that the controller 120 can execute the steps by using the substrate processing apparatus 10 to acquire a predetermined result, and functions as a program. Hereinafter, the process recipe and the control program may be collectively or individually referred to as a “program”. Further, the process recipe may also be simply referred to as a “recipe”. Thus, in the present specification, the term “program” may refer to the recipe alone, may refer to the control program alone, or may refer to both of the recipe and the control program. The RAM 121B functions as a memory area (work area) where a program or data read by the CPU 121A is temporarily stored.

The I/O port 121D is connected to components such as the temperature sensor 110, the atmospheric robot 30, the vacuum robot 70, the driving structure 50, the gate valve 24, the gate valve 28, the gate valve 104, the gas supply valve 43, the valve 45, the vacuum pump 46, the substrate mover 84, the first heater 94 and the second heater 98.

The CPU 121A is configured to read and execute the control program stored in the memory 121C, and to read the recipe stored in the memory 121C in accordance with an instruction such as an operation command inputted via the input/output device 122. For example, in accordance with contents of the read recipe, the CPU 121A is configured to be capable of controlling various operations such as transfer operations for the substrates 100 by the atmospheric robot 30, the vacuum robot 70, the driving structure 50 and the substrate mover 84, opening and closing operations of the gate valve 24, the gate valve 28 and the gate valve 104, a flow rate adjusting operation and a pressure adjusting operation by the gas supply valve 43, the valve 45 and the vacuum pump 46 and a temperature adjusting operation by the first heater 94 and the second heater 98.

The controller 120 may be embodied by installing the above-described program stored in an external memory 123 into the computer. For example, the external memory 123 may be constituted by a component such as a magnetic disk such as a hard disk, an optical disk such as a CD, a magneto-optical disk such as an MO and a semiconductor memory such as a USB memory. The memory 121C and the external memory 123 may be embodied by a non-transitory computer readable recording medium. Hereafter, the memory 121C and the external memory 123 may be collectively or individually referred to as a “recording medium”. Thus, in the present specification, the term “recording medium” may refer to the memory 121C alone, may refer to the external memory 123 alone, and may refer to both of the memory 121C and the external memory 123. Instead of the external memory 123, a communication interface such as the Internet and a dedicated line may be used for providing the program to the computer.

The controller 120 is further configured to acquire temperature information from the temperature sensor 110 after the temperature sensor 110 measures the temperature of the boat 32. The controller 120 obtains (calculates) the temperature of the substrate 100 based on the temperature information acquired as described above. According to the present embodiments, the temperature of the substrate 100 (which is located at a portion (of the vertical surface 39) corresponding to a temperature measurement position of the temperature sensor 110) is obtained based on the temperature information measured by the temperature sensor 110. For example, a relationship between a temperature of the portion (of the vertical surface 39) corresponding to the temperature measurement position and the temperature of the substrate 100 supported at the portion of the vertical surface 39 may be acquired in advance by experiments and the like, and the temperature of the substrate 100 may be calculated based on the relationship describe above. In addition, in a case where two or more substrates among the substrates 100 are supported at the portion (of the vertical surface 39) corresponding to the temperature measurement position by the temperature sensor 110, a temperature measured by the temperature sensor 110 at the temperature measurement position may be set as a temperature of each of the two or more substrates.

The controller 120 is further configured to control the rotation driver 62 of the driving structure 50 such that the vertical surface 39 of the boat 32 faces the window 106 when the temperature of the boat 32 is measured. Specifically, the controller 120 controls the rotation driver 62 of the driving structure 50 and adjusts (controls) the rotation angle of the boat 32 such that the vertical surface 39 of the boat 32 faces the temperature sensor 110 provided on the outer side of the window 106 when the temperature of the boat 32 is measured. When the temperature of the boat 32 is measured, the controller 120 controls the elevation driver 58 such that the vertical surface 39 of the boat 32 is moved (elevated or lowered) in the vertical direction with respect to the window 106 while the vertical surface 39 of the boat 32 faces the window 106. In such a state, a temperature of the vertical surface 39 is measured at a plurality of positions. In other words, while the temperature measurement range 111 of the temperature sensor 110 lies within the vertical surface 39 of the boat 32, the controller 120 performs an elevation operation of elevating or lowering the boat 32 supporting the substrates 100 so as to change relative positions of the vertical surface 39 and the temperature sensor 110 in an elevation direction (vertical direction) of the boat 32. By performing the elevation operation, the temperature sensor 110 measures temperatures at a plurality of positions on the vertical surface 39, and the controller 120 acquires temperature information at a plurality of measurement positions (temperature measurement positions) on the vertical surface 39. Further, when the temperature information of the plurality of measurement positions on the vertical surface 39 is acquired by the temperature sensor 110, the controller 120 acquires (or calculates) the temperature of each of the substrates 100 supported at the portion corresponding to each measurement position (temperature measurement position) based on the temperature information of each measurement position acquired as described above.

When the temperature of the boat 32 is measured, the controller 120 controls the driving structure 50 such that the boat 32 is moved upward and downward at least once. In other words, as one execution of the elevation operation, the controller 120 performs an operation of elevating (or lowering) the boat 32 from an initial position and then lowering (or elevating) the boat 32 so as to return the boat 32 to the initial position. In addition, when the boat 32 is elevated or lowered in the elevation operation, it is preferable to measure the temperature at the same position on the vertical surface 39 when the boat 32 is elevated and when the boat 32 is lowered. By measuring the temperature information a plurality number of times at the same measurement position as described above, the controller 120 acquires the temperature information the plurality number of times at the same measurement position. Further, when the temperature information is acquired the plurality number of times at the same measurement position, it is possible to obtain the temperature of the substrate 100 based on an average value of the temperature information acquired the plurality number of times or the latest temperature information.

Further, after the processed substrate 100 is supported by the boat 32 and cooled in the load lock chamber 14 for a predetermined time, by measuring the temperature of the boat 32 by using the temperature sensor 110, the controller 120 determines whether or not it is possible to transfer (or unload) the substrate 100 from the load lock chamber 14 to the atmospheric transfer chamber 12. According to the present embodiments, for example, the controller 120 determines that it is possible to unload the substrate 100 to the atmospheric transfer chamber 12 when the temperature of the boat 32 is equal to or less than a threshold value (which is set in advance and may also be referred to as “a threshold value for the boat 32”), and that it is not possible to unload the substrate 100 to the atmospheric transfer chamber 12 when the temperature of the boat 32 is greater than the threshold value. When the controller 120 determines that it is possible to unload the substrate 100, the gate valve 104 of the load lock chamber 14 is opened, and the atmospheric robot 30 unloads the substrate 100. On the other hand, when the controller 120 determines that it is not possible to unload the substrate 100, the controller 120 measures the temperature of the boat 32 again after a predetermined time has elapsed. Further, in a case where the temperature sensor 110 measures the temperatures at the plurality of positions on the vertical surface 39, the controller 120 may determine that it is not possible to unload the substrate 100 when the temperature information of at least one measurement position is greater than the threshold value. Further, in such a case, an average value of the temperatures measured at the plurality of positions on the vertical surface 39 may be calculated, and when the average value is greater than the threshold value, the controller 120 may determine that it is not possible to unload the substrate 100. Alternatively, the temperature of the substrate 100 may be obtained based on the temperature of the boat 32, and the controller 120 may determine whether or not it is possible to unload the substrate 100 based on whether or not the temperature of the substrate 100 is greater than a threshold value (which is set in advance) for the substrate 100. Further, in a case where the temperatures of the substrates 100 respectively supported at the plurality of positions are obtained by measuring the temperatures at the plurality of positions on the vertical surface 39, when the temperature of at least one among the substrates 100 is greater than the threshold value for the substrate 100, the controller 120 may determine that it is not possible to unload the substrate 100. For example, the threshold value for the substrate 100 may be substantially the same as the threshold value for the boat 32.

For example, the controller 120 may be further configured to control the transfer operation of the atmospheric robot 30 and the transfer operation of the vacuum robot 70 such that it is possible to change a path for transferring the substrate 100 between the atmospheric transfer chamber 12 and the transfer chamber 16 via the load lock chamber 14A or the load lock chamber 14B, based on the temperature of the vertical surface 39 or the substrate 100 measured by the temperature sensor 110 provided in the load lock chamber 14A and the temperature of the vertical surface 39 or the substrate 100 measured by the temperature sensor 110 provided in the load lock chamber 14B. Specifically, for example, by obtaining the temperatures of the substrates 100 supported by each boat 32 of the load lock chambers 14A and 14B, respectively, the controller 120 may estimate which of the load lock chamber 14A or the load lock chamber 14B allows the processed substrate 100 to be unloaded to the atmospheric transfer chamber 12 faster, and configured to change the path of a subsequent processed substrate 100 to the load lock chamber 14 where the processed substrate 100 can be unloaded faster.

For example, the controller 120 may be further configured to change a frequency of loading the processed substrates 100 from the transfer chamber 16 to the load lock chamber 14A and a frequency of loading the processed substrates 100 from the transfer chamber 16 to the load lock chamber 14B such that the temperature of the boat 32 obtained from the temperature sensor 110 in the load lock chamber 14A and the temperature of the boat 32 obtained from the temperature sensor 110 in the load lock chamber 14B get close to each other.

### <Method of Manufacturing Semiconductor Device>

Subsequently, a method of manufacturing the semiconductor device by using the substrate processing apparatus 10, that is, process sequences of the substrate processing of processing the substrate 100 will be described. Further, in the following description, as described above, operations of components constituting the substrate processing apparatus 10 are controlled by the controller 120.

First, the substrates 100 stored in the pods 27-1 through 27-3 are transferred into the atmospheric transfer chamber 12 by the atmospheric robot 30.

Subsequently, after setting (adjusting) the inner pressure of the load lock chamber 14 to the atmospheric pressure, the gate valve 104 is opened. Specifically, the gas supply valve 43 of the gas supply pipe 42 is opened to supply the inert gas into the load lock chamber 14. After setting the inner pressure of the load lock chamber 14 to the atmospheric pressure in a manner described above, the gate valve 104 is opened.

Subsequently, the substrate 100 is transferred (loaded) into the load lock chamber 14. Specifically, the substrate 100 loaded into the atmospheric transfer chamber 12 is transferred into the load lock chamber 14 by the atmospheric robot 30, and is placed on the support recess 40 of the boat 32. Thereby, the substrate 100 is supported by the boat 32.

Subsequently, after the gate valve 104 is closed, the inner pressure of the load lock chamber 14 is set to the vacuum pressure. Specifically, after a predetermined number of the substrates 100 are supported by the boat 32, the valve 45 of the exhaust pipe 44 is opened so as to exhaust the inside of the load lock chamber 14 by the vacuum pump 46. Thereby, it is possible to set the inner pressure of the load lock chamber 14 to the vacuum pressure. Further, when setting the inner pressure of the load lock chamber 14 to the vacuum pressure, an inner pressure of the transfer chamber 16 and an inner pressure of the process chamber 18 are also set to the vacuum pressure.

Subsequently, the substrate 100 is transferred from the load lock chamber 14 to the process chamber 18. Specifically, first, the gate valve 24 is opened. When opening the gate valve 24, the elevation driver 58 can elevate or lower the boat 32 such that the substrate 100 supported by the boat 32 is capable of being transferred (or taken out) by the vacuum robot 70. Further, the rotation driver 62 can rotate the boat 32 such that a substrate loading/unloading port of the boat 32 faces the transfer chamber 16.

The vacuum robot 70 extends the finger 78 of the arm structure 76 toward the boat 32 and places the substrate 100 on the finger 78. After retracting the finger 78, the vacuum robot 70 rotates the arm structure 76 such that the arm structure 76 faces the process chamber 18. Subsequently, the vacuum robot 70 extends the finger 78 such that the substrate 100 is loaded into the process chamber 18 through the communication structure 26 with the gate valve 28 opened.

In the process chamber 18, the substrate 100 placed on the finger 78 may be placed on the first mounting table 92 of the first process structure 80, or may be transferred to the mover 86 standing by on a side portion of the first process structure 80. After receiving the substrate 100, the mover 86 is rotated toward the second process structure 82 and places the substrate 100 on the second mounting table 96.

Then, in the process chamber 18, the substrate 100 is subjected to a predetermined process such as an ashing process. In the predetermined process, the temperature of the substrate 100 is elevated by being heated by a heater such as the first heater 94 and the second heater 98, or by being heated by a reaction heat generated by performing the predetermined process.

Subsequently, the substrate 100 after the predetermined process is performed (that is, the processed substrate 100) is transferred from the process chamber 18 to the load lock chamber 14. A transfer the substrate 100 from the process chamber 18 to the load lock chamber 14 is performed in an order reverse to that of loading the substrate 100 into the process chamber 18 described above. When transferring the substrate 100 from the process chamber 18 to the load lock chamber 14, the inside of the load lock chamber 14 is maintained in a vacuum state (that is, the inner pressure of the load lock chamber 14 is set to the vacuum pressure).

After the processed substrates 100 are loaded into the load lock chamber 14 and supported by the boat 32 in the multistage manner with the predetermined interval therebetween, the gate valve 24 is closed and the inner pressure of the load lock chamber 14 is set to the atmospheric pressure. Specifically, the gas supply valve 43 of the gas supply pipe 42 is opened to supply the inert gas into the load lock chamber 14. Thereby, the inner pressure of the load lock chamber 14 is set to the atmospheric pressure by supplying the inert gas. According to the present embodiments, the boat 32 and the substrates 100 supported by the boat 32 are cooled by the cooling structure (not shown) and the inert gas supplied into the load lock chamber 14. A cooling operation for the substrate 100 in the load lock chamber 14 is performed for a predetermined time T1. In addition, the inert gas supplied into the load lock chamber 14 may be cooled in advance in a location preceding the gas supply pipe 42 in order to promote the cooling operation.

Further, when the processed substrates 100 are completely loaded (placed) into the boat 32, the boat 32 is elevated or lowered to a position for cooling the processed substrates 100. According to the present embodiments, the cooling operation is performed while the boat 32 is elevated to the highest position such that the cooling by the cooling structure can be promoted.

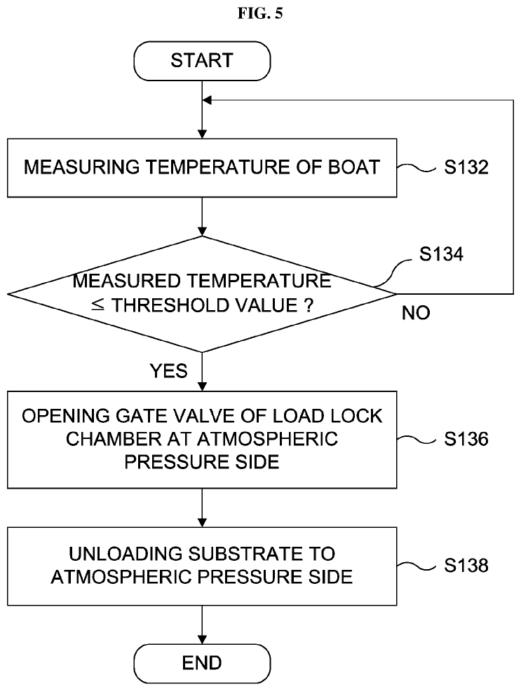

Subsequently, after the substrate 100 is cooled for the predetermined time T1, the controller 120 controls the temperature sensor 110 to start measuring the temperature of the boat 32 (that is, start a temperature measurement operation for the boat 32) as shown in FIG. 5 (step S132). In the step S132, the temperature sensor 110 measures the temperature of the boat 32 supporting the substrates 100. Specifically, the controller 120 controls the rotation driver 62 to rotate the boat 32 such that the vertical surface 39 of the boat 32 faces the temperature sensor 110 through the window 106. According to the present embodiments, the boat 32 is rotated to the same rotational position as the boat 32 when the substrate 100 is unloaded through the gate valve 104. Further, the controller 120 controls the elevation driver 58 elevate or lower the boat 32 such that the vertical surface 39 of the boat 32 is moved in the vertical direction relative to the temperature sensor 110 through the window 106. By allowing the temperature measurement range 111 of the temperature sensor 110 within the vertical surface 39 in a manner described above, it is possible to reliably measure the temperature of the vertical surface 39.

More specifically, after the boat 32 is rotated, the boat 32 elevated to the highest position thereof during the cooling operation is lowered to the lowest position thereof by the elevation driver 58. During such an operation, it is possible to measure the temperature of the vertical surface 39 from a lower end to an upper end thereof is scanned by temperature sensor 110. Further, after lowering the boat 32 to the lowest position, the boat 32 is elevated to the highest position again. Similarly, during such an operation, it is possible to measure the temperature of the vertical surface 39 from the upper end to the lower end thereof is scanned by temperature sensor 110. As a result, it is possible to measure the temperature of the vertical surface 39 from the upper end to the lower end of the vertical surface 39 at least twice or more, and thereby, it is possible to improve an accuracy of the temperature measurement. However, the temperature measurement operation may not be performed over an entirety of the vertical surface 39 from the lower end to the upper end thereof. For example, by measuring the temperatures at least at the plurality of measurement points, it is possible to acquire a temperature distribution of the substrates 100 supported by the boat 32.

Subsequently, the controller 120 acquires temperature information of the boat 32 measured by the temperature sensor 110, and compares the temperature information acquired as described above with the threshold value (which is set in advance) (step S134). In the step S134, in a case where the temperature information acquired as described above is equal to or less than the threshold value, the controller 120 determines that the substrate 100 supported by the boat 32 is sufficiently cooled, and the present process proceeds to a step S136. On the other hand, in a case where the temperature information acquired as described above is greater than the threshold value, the controller 120 determines that the substrate 100 supported by the boat 32 is not sufficiently cooled, and the present process returns to the step S132. When returning to the step S132, for example, the step S132 is executed after the predetermined time T1 has elapsed. Further, a time until the step S132 is re-executed may be set to a predetermined time T2 which is shorter than the predetermined time T1. Further, the controller 120 may calculate a difference between the temperature information acquired as described above and the threshold value, and may set the time until the step S132 is re-executed to be different according to the difference calculated as described above.

In the step S134, the controller 120 compares the temperature information of the boat 32 acquired from the temperature sensor 110 with the threshold value. However, in the step S134, the controller 120 may calculate the temperature of each of the substrates 100 supported at the portion corresponding to each measurement position based on the temperature information of the boat 32 acquired as described above, and may compare the temperature of the substrate 100 calculated as described above with the threshold value (which is set in advance) for the substrate 10 so as to perform a determination substantially similar to that of the step S134.

Further, it is preferable that the inert gas is continuously supplied through the gas supply pipe 42 at least until it is determined in the step S134 that the substrate 100 is sufficiently cooled. In such a case, the valve 45 of the exhaust pipe 44 is opened with a small degree of opening, and the load lock chamber 14 is continuously exhausted by the vacuum pump 46 such that the inner pressure of the load lock chamber 14 is maintained at a constant pressure.

In the step S136, the gate valve 104 is opened. For example, the present embodiments are described by way of an example in which the inner pressure of the load lock chamber 14 is set (adjusted) to the atmospheric pressure after the substrate 100 is loaded into the load lock chamber 14. However, the inner pressure of the load lock chamber 14 may be set to the atmospheric pressure after it is determined in the step S134 that the substrate 100 is sufficiently cooled (that is, it is possible to unload the substrate 100). However, from a viewpoint of improving a throughput and improving a cooling speed of the substrate 100, it is preferable that the inner pressure of the load lock chamber 14 is set to the atmospheric pressure immediately after the substrates 100 are loaded into the load lock chamber 14.

Subsequently, the substrate 100 (which is cooled in a manner described above) is unloaded from the load lock chamber 14 to an atmospheric pressure region (for example, the atmospheric transfer chamber 12). Specifically, the substrate 100 is transferred from the load lock chamber 14 with the gate valve 104 open to the atmospheric transfer chamber 12 by using the atmospheric robot 30. Thereby, the transfer operation of the substrate 100 is completed. Further, by transferring the substrate 100 (which is cooled) to the atmospheric transfer chamber 12, a process of manufacturing the semiconductor device on the substrate 100 is completed.

### <Program>

A program according to the present embodiments is a program that causes a processing apparatus of the substrate 100 (that is, the substrate processing apparatus 10) (which includes: the load lock chamber 14 where the substrate 100 is loaded or unloaded; the boat 32 provided in the load lock chamber 14 and configured to support the substrates 100 in the multistage manner with the predetermined interval therebetween; and the temperature sensor 110 capable of measuring the temperature of the boat 32 in the non-contact manner while the substrates 100 are supported by the boat 32) to perform: (a) loading the processed substrates 100 into the load lock chamber 14 and supporting the substrates 100 by the boat 32 provided in the load lock chamber 14 in the multistage manner with the predetermined interval therebetween; and (b) measuring the temperature of the boat 32 in the non-contact manner by the temperature sensor 110 while the substrates 100 are supported by the boat 32.

Subsequently, operations and effects according to the present embodiments will be described. When the temperature of the substrate 100 unloaded from the load lock chamber 14 fluctuates, the substrate 100 at a high temperature may react with an atmosphere at a low temperature, causing an undesirable oxidation or damaging the semiconductor device or components. Therefore, it is preferable to obtain the temperature of the processed substrate 100 in the load lock chamber 14. For example, when a contact type temperature sensor such as a thermocouple (TC) is used, particles may be generated due to a contact between the substrate 100 and the thermocouple TC. Further, in a case where the boat 32 is driven, it may be difficult to wire a component such as the thermocouple TC. Therefore, it is preferable to measure the temperature of the substrate 100 by using a temperature sensor (non-contact type temperature sensor) capable of performing a non-contact type temperature measurement. However, when the temperature of the substrate 100 is directly measured by the non-contact type temperature sensor, it may be difficult to accurately measure the temperature of the substrate 100 depending on a type of the substrate 100 and the position of the substrate 100 in the load lock chamber 14. For example, when measuring a temperature of a substrate (for example, a semiconductor wafer such as a silicon wafer) made of a material whose infrared emissivity varies greatly with the temperature thereof by using the non-contact type temperature sensor such as the radiation thermometer configured to measure the temperature based on a specific emissivity, it may be difficult to accurately measure the temperature of the substrate such as the silicon wafer. In addition, when measuring the temperature of the substrate such as the silicon wafer made of a material whose infrared transmittance is high (whose emissivity is low), since an infrared light from another heat source may be transmitted through the substrate and the infrared light may be received by the non-contact type temperature sensor, it may not be possible to accurately measure the temperature of the substrate itself, which is an object of the temperature measurement. In addition, since an amount of the infrared light transmitted as described above may differ depending on positions of the substrates in the load lock chamber 14, it may not be possible to accurately measure the temperature of each of the substrates.

On the other hand, according to the present embodiments, it is possible to accurately control (manage) the temperature of the substrate 100 unloaded from the load lock chamber 14 by obtaining the temperature of the substrate unloaded from the load lock chamber 14. Therefore, for example, by limiting the temperature of the substrate 100 unloaded from the load lock chamber 14, it is possible to prevent (or suppress) the substrate 100 at the high temperature from reacting with the atmosphere at the low temperature, causing the undesirable oxidation or damaging the semiconductor device or the components. Further, for example, it is possible to suppress a non-uniformity of the temperature of the substrate 100 unloaded from the load lock chamber 14, and as a result, it is possible to reduce an influence according to the non-uniformity of the temperature of the substrate 100 (for example, a non-uniformity in a degree of oxidation and the like).

Further, according to the present embodiments, by providing the temperature sensor 110 configured to measure the temperature of the boat 32 (which supports the substrate 100) in the non-contact manner, it is possible to accurately obtain the temperature of the substrate 100 supported by the boat 32 regardless of the type of the substrate 100 (especially, characteristics such as a reflectance and a transmittance) and the position of the substrate 100 in the load lock chamber 14, and it is also possible to easily control (or manage) the temperature of the substrate 100.

Further, according to the present embodiments, the controller 120 can obtain the temperature of the substrate 100 based on the temperature of the boat 32 measured by the temperature sensor 110. Therefore, it is possible to accurately obtain the temperature of the substrate 100 supported by the boat 32.

Further, according to the present embodiments, the vertical surface 39 of the boat 32 is set to be wider than a spot diameter of the temperature sensor 110 (that is, the temperature measurement range 111). When the temperature of the boat 32 is measured, by rotating the boat 32 to a position where the substrate 100 is not within the spot diameter of the temperature sensor 110, it is possible to accurately measure the temperature of the boat 32.

According to the present embodiments, since the temperatures of the plurality of positions on the vertical surface 39 corresponding to the substrates 100 supported by the boat 32 are measured, it is possible to calculate the temperature of each of the substrates 100.

Further, according to the present embodiments, by rotating the boat 32 such that the vertical surface 39 faces the temperature sensor 110, an entirety of the temperature measurement range 111 of the temperature sensor 110 is set to be within the vertical surface 39. Thereby, it is possible to accurately obtain the temperature of the substrate 100 based on the temperature measurement of the boat 32.

According to the present embodiments, the temperatures are measured and acquired at the plurality of positions on the boat 32 by the temperature sensor 110 which is fixed. Therefore, it is possible to obtain the temperature of the substrate 100 placed at each position on the vertical surface 39 of the boat 32 whose temperature is measured and obtained by the temperature sensor 110.

According to the present embodiments, by performing the elevation operation after the vertical surface 39 of the boat 32 faces the temperature sensor 110 through the window 106, it is possible to more accurately measure and obtain the temperature of the vertical surface 39 by the temperature sensor 110 which is fixed. In addition, by continuously measuring the temperatures at the plurality of positions on the vertical surface 39 of the boat 32 a plurality number of times (twice or more), it is possible to measure the temperature more stably (that is, it is possible to suppress an influence of a disturbance).

According to the present embodiments, by increasing the inner pressure of the load lock chamber 14 with the inert gas, it is possible to promote a heat dissipation from the substrate 100 supported in the load lock chamber 14, and it is also possible to cool the substrate 100 within the load lock chamber 14. Further, by measuring the temperature of the boat 32, it is possible to obtain the temperature of the substrate 100 cooled in an inert gas atmosphere. Thereby, it is possible to unload the substrate 100 in the load lock chamber 14 after the substrate 100 is cooled until the temperature of the substrate 100 is equal to or less than the threshold value set in advance.

According to the present embodiments, by providing the temperature sensor 110 at the outer side of the load lock chamber 14, it is possible to easily install the temperature sensor 110 or to perform a maintenance operation of the temperature sensor 110. Further, as the temperature sensor 110, it is possible to use a temperature sensor whose heat resistance is not high.

According to the present embodiments, for example, the boat 32 is made of a material such as aluminum whose variation (change) in an infrared emissivity with respect to a temperature variation in a temperature range to be measured is smaller than that of the material constituting the substrate 100 described above. Then, by measuring the temperature of the boat 32 while the substrate 100 is supported by the boat 32, even when the substrate 100 is made of the material whose infrared emissivity varies (changes) greatly with the temperature variation, it is possible to accurately obtain the temperature of the substrate 100 supported by the boat 32 and it is also possible to easily control (manage) the temperature of the substrate 100. Further, according to the present embodiments, for example, the boat 32 is made of a material such as aluminum whose infrared transmittance or whose infrared reflectance (preferably, both of the infrared transmittance and the infrared reflectance) in the temperature range to be measured is smaller than that of the material constituting the substrate 100 described above (or whose emissivity is greater than that of the material constituting the substrate 100 described above). Therefore, it is possible to accurately obtain the temperature of the substrate 100 supported by the boat 32 regardless of the type of the substrate 100 (in particular, the characteristics such as the reflectance and the transmittance) and the position of the substrate 100 in the load lock chamber 14, and it is also possible to easily control (or manage) the temperature of the substrate 100. In particular, it is preferable that the material constituting the boat 32 is substantially opaque to the infrared light.

Further, according to the present embodiments, the alumite treatment is performed on at least a surface of the vertical surface 39 such that the infrared reflectance thereof becomes smaller than that of the substrate 100 (that is, the emissivity thereof becomes larger than that of the substrate 100). Thereby, it is possible to more remarkably obtain the effects described above effects.

According to the present embodiments, since a thickness of a portion (for example, the one of the support columns 38 described above) corresponding to the vertical surface 39 is set to be constant, a correlation between the temperatures of the substrates 100 stacked in the boat 32 and the temperature of the boat 32 measured as described above becomes constant. Thereby, it is possible to easily obtain the temperature of the substrate 100.

According to the present embodiments, since the controller 120 is configured to change the path (transfer path) of the substrate 100 in accordance with the conditions, by reducing a temperature deviation of the substrate 100 unloaded from the load lock chamber 14 or by reducing a temperature deviation of the boat 32, it is possible to shorten a cooling time of the substrate 100.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof. For example, the embodiments described above are described by way of an example in which the temperature sensor 110 is arranged on the lower portion of the outer peripheral wall 15C of the load lock chamber 14. However, the technique of the present disclosure is not limited thereto. For example, the temperature sensor 110 may be provided at any position in the load lock chamber 14 as long as the temperature of the upper end of the boat 32 and the temperature of the lower end of the boat 32 can be measured by the temperature sensor 110. In addition, the window 106 is provided at a portion of the outer peripheral wall 15C where the temperature sensor 110 is provided.

For example, the embodiments described above are described by way of an example in which the temperature measurement operation of the boat 32 by the temperature sensor 110 is performed after the cooling operation of the substrate 100 in the load lock chamber 14 is performed for a predetermined time. However, the technique of the present disclosure is not limited thereto. Alternatively, for example, a temperature of a part of the boat 32 may be continuously measured while the substrate 100 is being cooled in the load lock chamber 14, and when the temperature information from the temperature sensor 110 measuring the temperature of the part of the boat 32 becomes equal to or less than a threshold value which is set in advance, the temperature of the boat 32 may be measured by temperature sensor 110.

For example, the embodiments described above are described by way of an example in which the window 106 is provided at the load lock chamber 14 and the temperature sensor 110 is arranged at the window 106. However, the technique of the present disclosure is not limited thereto. Alternatively, for example, a plurality of windows including the window 106 may be provided at the load lock chamber 14 and a plurality of temperature sensor including the temperature sensors 110 may be arranged at the plurality of windows 106, respectively. Alternatively, for example a single large window serving as the window 106 may be provided and the plurality of temperature sensor including the temperature sensors 110 may be arranged at the single large window serving as the window 106.

For example, the embodiments described above are described by way of an example in which the transfer operation of unloading the substrate 100 from the load lock chamber 14 to the atmospheric pressure region is stopped when the temperature of the boat 32 is greater than the threshold value. However, the technique of the present disclosure is not limited thereto. For example, an alarm notification may be transmitted through an interface along with a stop of the transfer operation of unloading the substrate 100.

Further, the entire contents of Japanese Patent Application No. 2021-041543, filed on Mar. 15, 2021, are hereby incorporated in the present specification by reference. All documents, patent applications, and technical standards described in the present specification are hereby incorporated in the present specification by reference to the same extent that the contents of each of the documents, the patent applications and the technical standards are specifically described.

According to some embodiments of the present disclosure, it is possible to obtain the temperature of the substrate in the load lock chamber.

What is claimed is:

1. A substrate processing apparatus comprising:
a load lock chamber into which a substrate is loaded and from which the substrate is unloaded;
a substrate support provided in the load lock chamber and configured to support a plurality of substrates comprising the substrate in a multistage manner with a predetermined interval therebetween; and
a temperature sensor capable of measuring a temperature of the substrate support in a non-contact manner while the plurality of substrates are supported by the substrate support.

2. The substrate processing apparatus of claim 1, further comprising:
a controller configured to be capable of obtaining a temperature of the substrate based on the temperature of the substrate support measured by the temperature sensor.

3. The substrate processing apparatus of claim 2, wherein the substrate support is provided with a vertical surface extending in a direction perpendicular to a surface of the substrate supported by the substrate support, and
wherein an infrared transmittance of the vertical surface is set to be lower than an infrared transmittance of the substrate.

4. The substrate processing apparatus of claim 1, wherein the substrate support is provided with a vertical surface extending in a direction perpendicular to a surface of the substrate supported by the substrate support, and
wherein the temperature sensor is configured to measure a temperature of the vertical surface of the substrate support in the non-contact manner while the plurality of substrates are supported by the substrate support.

5. The substrate processing apparatus of claim 4, further comprising:
a rotation driver configured to rotate the substrate support about an axis extending along a direction in which the plurality of substrates are stacked in the multistage manner; and
a controller configured to be capable of controlling the rotation driver to perform a rotation operation of rotating the substrate support up to an angle at which the vertical surface faces the temperature sensor while the plurality of substrates are supported by the substrate support.

6. The substrate processing apparatus of claim 5, wherein the controller is further configured to be capable of acquiring the temperature of the substrate support measured by the temperature sensor after the rotation operation is performed.

7. The substrate processing apparatus of claim 6, wherein the controller is further configured to be capable of rotating the substrate support in the rotation operation such that an entirety of a temperature measurement range of the temperature sensor lies within the vertical surface when acquiring the temperature of the substrate support measured by the temperature sensor.

8. The substrate processing apparatus of claim 1, further comprising:
an elevation driver configured to elevate or lower the substrate support along a direction in which the plurality of substrates are stacked in the multistage manner; and
a controller configured to be capable of acquiring the temperature of the substrate support measured by the temperature sensor and capable of controlling the elevation driver to perform an elevation operation of elevating or lowering the substrate support, and
wherein the substrate support is provided with a vertical surface extending in a direction perpendicular to a surface of the substrate supported by the substrate support, and
wherein the controller is further configured to be capable of controlling the elevation driver to perform the elevation operation while the plurality of substrates are supported by the substrate support such that relative positions of the vertical surface and the temperature sensor in an elevation direction of the substrate support are capable of being changed in a state where a temperature measurement range of the temperature sensor lies within the vertical surface, and capable of controlling the temperature sensor to measure temperatures at a plurality of measurement positions on the vertical surface.

9. The substrate processing apparatus of claim 8, further comprising:
a rotation driver configured to rotate the substrate support about an axis extending along a direction in which the plurality of substrates are stacked in the multistage manner,
wherein the controller is further configured to be capable of controlling the rotation driver to perform a rotation operation of rotating the substrate support up to an angle at which the vertical surface faces the temperature sensor while the plurality of substrates are supported by the substrate support and then controlling the elevation driver to perform the elevation operation such that the temperature sensor measures the temperatures at the plurality of measurement positions on the vertical surface.

10. The substrate processing apparatus of claim 8, wherein the controller is further configured to be capable of controlling the elevation driver such that the temperature sensor measures the temperatures at the plurality of measurement positions on the vertical surface a plurality number of times by continuously moving the substrate support upward and downward at least once in the elevation operation.

11. The substrate processing apparatus of claim 10, wherein the controller is further configured to be capable of obtaining an average value of temperatures acquired the plurality number of times at a measurement position among the plurality of measurement positions in the elevation operation as a temperature of the measurement position.

12. The substrate processing apparatus of claim 11, wherein the controller is further configured to be capable obtaining a temperature of the substrate supported at a position on the vertical surface corresponding to the measurement position based on the temperature of the measurement position.

13. The substrate processing apparatus of claim 8, further comprising:
an inert gas supplier configured to supply an inert gas into the load lock chamber,
wherein the controller is further configured to be capable of controlling the inert gas supplier to supply the inert gas and capable of increasing an inner pressure of the load lock chamber by supplying the inert gas into the load lock chamber where the substrate is loaded.

14. The substrate processing apparatus of claim 13, wherein the controller is further configured to be capable of controlling the temperature sensor to measure the temperatures at the plurality of measurement positions on the vertical surface by performing the elevation operation after the inert gas is supplied into the load lock chamber for a predetermined time.

15. The substrate processing apparatus of claim 14, wherein the controller is further configured to be capable of, when at least one among the temperatures at the plurality of measurement positions on the vertical surface acquired by the temperature sensor is greater than a threshold value set in advance, continuously supplying the inert gas while the plurality of substrates are supported by the substrate support until a predetermined time has elapsed, and obtaining the temperature of the substrate support measured by the temperature sensor by performing the elevation operation again after a predetermined time has elapsed.

16. The substrate processing apparatus of claim 15, further comprising:
an atmospheric transfer structure capable of transferring the substrate between the load lock chamber and an atmospheric transfer chamber,
wherein the controller is further configured to be capable of controlling a transfer operation of the atmospheric transfer structure, and capable of controlling the atmospheric transfer structure to unload the plurality of substrates from the load lock chamber by the atmospheric transfer structure when at least one among the temperatures at the plurality of measurement positions on the vertical surface acquired by the temperature sensor is equal to or less than the threshold value set in advance.

17. The substrate processing apparatus of claim 1, further comprising:
an atmospheric transfer chamber connected to a first portion of the load lock chamber;
a vacuum transfer chamber connected to a second portion of the load lock chamber;
an atmospheric transfer structure provided in the atmospheric transfer chamber and configured to be capable of transferring the substrate between the atmospheric transfer chamber and the load lock chamber;
a vacuum transfer structure provided in the vacuum transfer chamber and configured to be capable of transferring the substrate between the vacuum transfer chamber and the load lock chamber; and
a controller configured to be capable of controlling a transfer operation of the atmospheric transfer structure and a transfer operation of the vacuum transfer structure so as to change a path for transferring the substrate between the atmospheric transfer chamber and the vacuum transfer chamber via a first load lock chamber among a plurality of load lock chambers comprising the load lock chamber or a second load lock chamber among the plurality of load lock chambers based on a temperature measured by the temperature sensor provided in the first load lock chamber and a temperature measured by the temperature sensor provided in the second load lock chamber.

18. The substrate processing apparatus of claim 17, wherein the controller is configured to be capable of changing a frequency of loading the substrate from the vacuum transfer chamber to the first load lock chamber and a frequency of loading the substrate from the vacuum transfer chamber to the second load lock chamber such that the temperature of the substrate support measured by the temperature sensor provided in the first load lock chamber and the temperature of the substrate support measured by the temperature sensor provided in the second load lock chamber get close to each other.

19. A method of manufacturing a semiconductor device, comprising:
(a) loading a plurality of substrates into a load lock chamber and supporting the plurality of substrates in a multistage manner with a predetermined interval therebetween by a substrate support provided in the load lock chamber; and
(b) measuring a temperature of the substrate support in a non-contact manner by a temperature sensor while the plurality of substrates are supported by the substrate support.

20. A non-transitory computer-readable recording medium storing a program that causes, by a computer, a substrate processing apparatus to perform:
(a) loading a plurality of substrates into a load lock chamber and supporting the plurality of substrates in a multistage manner with a predetermined interval therebetween by a substrate support provided in the load lock chamber; and
(b) measuring a temperature of the substrate support in a non-contact manner by a temperature sensor while the plurality of substrates are supported by the substrate support.
